(19) United States
(12) Patent Application Publication
(10) Pub. No.: US 2024/0321918 A1
(43) Pub. Date: Sep. 26, 2024

(54) SOLID-STATE IMAGING ELEMENT AND ELECTRONIC EQUIPMENT

(71) Applicant: SONY SEMICONDUCTOR SOLUTIONS CORPORATION, KANAGAWA (JP)

(72) Inventor: MASAYUKI SUZUKI, KANAGAWA (JP)

(21) Appl. No.: 18/580,112

(22) PCT Filed: Jun. 17, 2022
(86) PCT No.: PCT/JP2022/024403

§ 371 Date: Jan. 17, 2024

(30) Foreign Application Priority Data
Aug. 6, 2021 (JP) 2021-129676

(51) Int. Cl. H01L 27/146

(52) U.S. Cl. CPC H01L 27/14627; H01L 27/14645

(57) ABSTRACT

A solid-state imaging element (1) according to the present disclosure includes a plurality of photoelectric conversion units, an on-chip lens, a prism portion (P), and a plurality of color splitters CS1. The plurality of photoelectric conversion units is disposed side by side in a matrix form in a semiconductor layer (20). The on-chip lens is disposed further on a light incident side than the semiconductor layer (20) to be shared by the plurality of photoelectric conversion units. The prism portion (P) is disposed between the on-chip lens and the plurality of photoelectric conversion units. The plurality of color splitters (CS1) are disposed between the prism portion (P) and the plurality of photoelectric conversion units.

### FIELD

The present disclosure relates to a solid-state imaging element and electronic equipment.

### BACKGROUND

In recent years, digital cameras have become increasingly popular, and there is an increasing demand for a solid-state imaging element (an image sensor), which is a main component of the digital cameras. Accordingly, technology development for realizing high image quality and high functionality has been actively performed in a solid-state imaging element (see, for example, Patent Literature 1).

### CITATION LIST

### Patent Literature

Patent Literature 1: JP 2017-157801 A

### SUMMARY

### Technical Problem

However, in the related art described above, there is room for further improvement in terms of improving image quality.

Therefore, the present disclosure proposes a solid-state imaging element and electronic equipment that can improve image quality.

### Solution to Problem

According to the present disclosure, there is provided a solid-state imaging element. The solid-state imaging element includes a plurality of photoelectric conversion units, an on-chip lens, a prism portion, and a plurality of color splitters. The plurality of photoelectric conversion units is disposed side by side in a matrix form in a semiconductor layer. The on-chip lens is disposed further on a light incident side than the semiconductor layer to be shared by the plurality of photoelectric conversion units. The prism portion is disposed between the on-chip lens and the plurality of photoelectric conversion units. The plurality of color splitters are disposed between the prism portion and the plurality of photoelectric conversion units.

### Advantageous Effects of Invention

According to the present disclosure, it is possible to provide a solid-state imaging element and electronic equipment that can improve image quality. Note that the effects described herein are not necessarily limited and may be any of the effects described in the present disclosure.

### BRIEF DESCRIPTION OF DRAWINGS

FIG. 1 is a system configuration diagram illustrating a schematic configuration example of a solid-state imaging element according to an embodiment of the present disclosure.

FIG. 2 is a sectional view schematically illustrating structure of a pixel array unit according to the embodiment of the present disclosure.

FIG. 3 is a plan view illustrating a configuration of a photodiode group according to the embodiment of the present disclosure.

FIG. 4 is a diagram for explaining a principle of a color splitter according to the embodiment of the present disclosure.

FIG. 5 is a diagram illustrating an incident state of incident light in the pixel array unit according to the embodiment of the present disclosure.

FIG. 6 is a sectional view schematically illustrating structure of a pixel array unit according to a modification 1 of the embodiment of the present disclosure.

FIG. 7 is a plan view illustrating a configuration of a photodiode group according to the modification 1 of the embodiment of the present disclosure.

FIG. 8 is a diagram illustrating an incident state of incident light in the pixel array unit according to the modification 1 of the embodiment of the present disclosure.

FIG. 9 is a diagram illustrating a configuration of a pixel array unit and an incident state of incident light according to a modification 2 of the embodiment of the present disclosure.

FIG. 10 is a plan view illustrating a configuration of a photodiode group according to the modification 2 of the embodiment of the present disclosure.

FIG. 11 is a diagram illustrating a configuration of a pixel array unit and an incident state of incident light according to a modification 3 of the embodiment of the present disclosure.

FIG. 12 is a sectional view schematically illustrating structure of a pixel array unit according to a modification 4 of the embodiment of the present disclosure.

FIG. 13 is a sectional view schematically illustrating structure of a pixel array unit according to a modification 5 of the embodiment of the present disclosure.

FIG. 14 is a diagram illustrating a configuration of a pixel array unit and an incident state of incident light according to a modification 6 of the embodiment of the present disclosure.

FIG. 15 is a perspective view schematically illustrating structure of a pixel array unit according to a modification 7 of the embodiment of the present disclosure.

FIG. 16 is a plan view illustrating an example of disposition of a plurality of photodiode groups according to a modification 8 of the embodiment of the present disclosure.

FIG. 17 is a plan view illustrating an example of disposition of a plurality of photodiode groups according to a modification 9 of the embodiment of the present disclosure.

FIG. 18 is a plan view illustrating an example of disposition of a plurality of photodiode groups according to a modification 10 of the embodiment of the present disclosure.

FIG. 19 is a block diagram illustrating a configuration example of an imaging device functioning as electronic equipment to which a technique according to the present disclosure is applied.

### DESCRIPTION OF EMBODIMENTS

Embodiments of the present disclosure are explained in detail below with reference to the drawings. Note that, in the embodiments explained below, redundant explanation is omitted by denoting the same parts with the same reference numerals and signs.

In recent years, digital cameras have become increasingly popular, and there is an increasing demand for a solid-state imaging element (an image sensor), which is a main component of the digital cameras. Accordingly, technology development for realizing high image quality and high functionality has been actively performed in the solid-state imaging element.

For example, there has been proposed a solid-state imaging element in which a photoelectric conversion unit that photoelectrically converts light in one wavelength region is provided on a light incident side and two photoelectric conversion units that photoelectrically convert light in other two different wavelength regions are provided on the opposite side of the light incident side.

However, in the related art explained above, since only light in three different wavelength regions can be photoelectrically converted, there is room for further improvement in terms of improving image quality.

Therefore, it is expected to realize a technique that can overcome the problems described above and improve the image quality of a solid-state imaging element.

### [Configuration of a Solid-State Imaging Element]

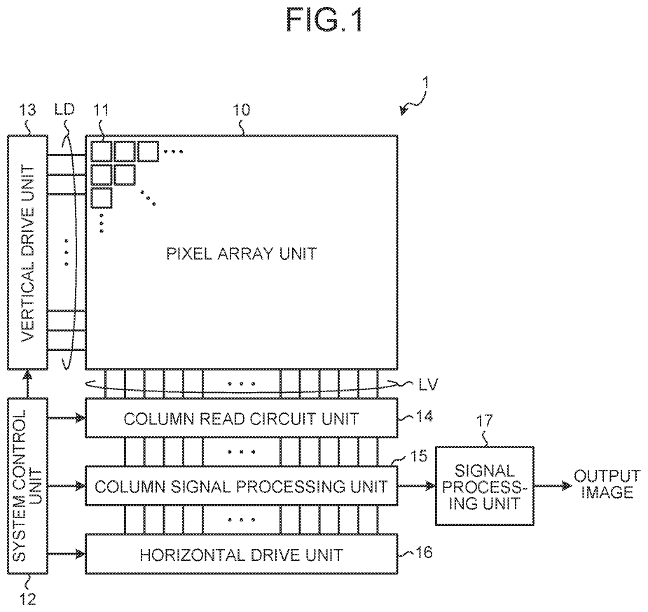

FIG. 1 is a system configuration diagram illustrating a schematic configuration example of a solid-state imaging element 1 according to an embodiment of the present disclosure. As illustrated in FIG. 1, the solid-state imaging element 1, which is a CMOS image sensor, includes a pixel array unit 10, a system control unit 12, a vertical drive unit 13, a column read circuit unit 14, a column signal processing unit 15, a horizontal drive unit 16, and a signal processing unit 17.

The pixel array unit 10, the system control unit 12, the vertical drive unit 13, the column read circuit unit 14, the column signal processing unit 15, the horizontal drive unit 16, and the signal processing unit 17 are provided on the same semiconductor substrate or on a plurality of electrically connected laminated semiconductor substrates.

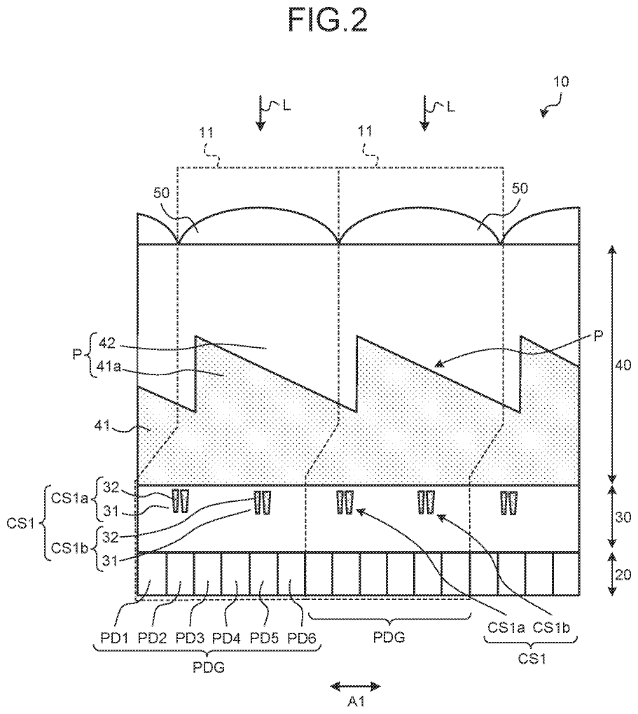

In the pixel array unit 10, effective unit pixels 11 having photoelectric conversion elements (photodiodes PD1 to PD6 (see FIG. 2) and the like) capable of photoelectrically converting a charge amount corresponding to an incident light amount, accumulating the charge amount on the inside, and outputting the charge amount as a signal are two-dimensionally disposed in a matrix. Note that, in the following explanation, the effective unit pixels 11 are also referred to as “unit pixels 11”.

The pixel array unit 10 sometimes includes a region where dummy unit pixels having structure not including the photodiodes PD1 to PD6, light-blocking unit pixels that shield light receiving surfaces from light to block light incidence from the outside, and the like are disposed in rows and/or columns besides the effective unit pixels 11.

Note that the light-blocking unit pixels may have the same configuration as the configuration of the effective unit pixel 11 except a structure in which the light-receiving surface is shielded from light. In the following explanation, photoelectric charges of a charge amount corresponding to an incident light amount are also simply referred to as “charges” and the unit pixels 11 are also simply referred to as “pixels”.

In the pixel array unit 10, pixel drive lines LD are formed for each of the rows in the left-right direction in the drawing (an array direction of pixels in pixel rows) and vertical pixel wires LV are formed for each of the columns in the up-down direction in the drawing (an array direction of pixels in pixel columns) with respect to the pixel array in a matrix. One ends of the pixel drive lines LD are connected to output ends corresponding to the rows of the vertical drive unit 13.

The column read circuit unit 14 includes at least a circuit that supplies a constant current to the unit pixels 11 in a selected row in the pixel array unit 10 for each of the columns and a current mirror circuit, a changeover switch for the unit pixel 11 to be read, and the like.

The column read circuit unit 14 configures an amplifier in conjunction with a transistor in the selected pixel in the pixel array unit 10, converts a photoelectric charge signal into a voltage signal, and outputs the voltage signal to the vertical pixel wires LV.

The vertical drive unit 13 includes a shift register and an address decoder and drives all the unit pixels 11 of the pixel array unit 10 simultaneously or drives the unit pixels 11 in units of rows. Although a specific configuration of the vertical drive unit 13 is not illustrated, the vertical drive unit 13 has a configuration including a read scanning system and a sweep scanning system or a batch sweeping and batch transfer system.

In order to read a pixel signal from the unit pixels 11, the read scanning system selectively scans the unit pixels 11 of the pixel array unit 10 in row units in order. In the case of row driving (a rolling shutter operation), about sweeping, sweep scanning is performed, earlier than read scanning by a time of shutter speed, on a read row on which the read scanning is performed by the read scanning system.

In the case of global exposure (a global shutter operation), batch sweeping is performed earlier than batch transfer by the time of the shutter speed. By such sweeping, unnecessary charges are swept (reset) from the photodiodes PD1 to PD6 and the like of the unit pixels 11 in the read row. Then, a so-called electronic shutter operation is performed by sweeping (resetting) the unnecessary charges.

Here, the electronic shutter operation refers to an operation of discarding unnecessary photoelectric charges accumulated in the photodiodes PD1 to PD6 and the like immediately before the electronic shutter operation and starting exposure (starting accumulation of photoelectric charges).

A signal read by the read operation by the read scanning system corresponds to an amount of light made incident after the immediately preceding read operation or electronic shutter operation. In the case of the row drive, a period from read timing by the immediately preceding read operation or sweep timing by the electronic shutter operation to read timing by the current read operation is a photoelectric charge storage time (exposure time) in the unit pixels 11. In the case of the global exposure, a time from the batch sweeping to the batch transfer is an accumulation time (an exposure time).

Pixel signals output from the unit pixels 11 of the pixel row selectively scanned by the vertical drive unit 13 are supplied to the column signal processing unit 15 through each of the vertical pixel wires LV. The column signal processing unit 15 performs predetermined signal processing on the pixel signals output from the unit pixels 11 of the selected row through the vertical pixel wires LV for each of the pixel columns of the pixel array unit 10 and temporarily retains the pixel signals after the signal processing.

Specifically, the column signal processing unit 15 performs at least noise removal processing, for example, CDS (Correlated Double Sampling) processing as the signal processing. By the CDS processing by the column signal processing unit 15, fixed pattern noise specific to pixels such as reset noise and threshold variation of an amplification transistor AMP is removed.

Note that the column signal processing unit 15 can be imparted with, for example, an AD conversion function besides the noise removal processing and configured to output a pixel signal as a digital signal.

The horizontal drive unit 16 includes a shift register and an address decoder and sequentially selects unit circuits corresponding to the pixel columns of the column signal processing unit 15. By the selective scanning by the horizontal drive unit 16, the pixel signals subjected to the signal processing by the column signal processing unit 15 are sequentially output to the signal processing unit 17.

The system control unit 12 includes a timing generator that generates various timing signals. The system control unit 12 performs drive control for the vertical drive unit 13, the column signal processing unit 15, the horizontal drive unit 16, and the like based on various timing signals generated by the timing generator.

The solid-state imaging element 1 further includes a signal processing unit 17 and a not-illustrated data storage unit. The signal processing unit 17 has at least an addition processing function and performs various kinds of signal processing such as addition processing on a pixel signal output from the column signal processing unit 15.

In the signal processing in the signal processing unit 17, the data storage unit temporarily stores data necessary for the processing. The signal processing unit 17 and the data storage unit may be an external signal processing unit provided on a substrate different from a substrate on which the solid-state imaging element 1 is provided, may perform, for example, processing by a DSP (Digital Signal Processor) or software, or may be mounted on the same substrate as the substrate on which the solid-state imaging element 1 is mounted.

### [Configuration of the Pixel Array Unit]

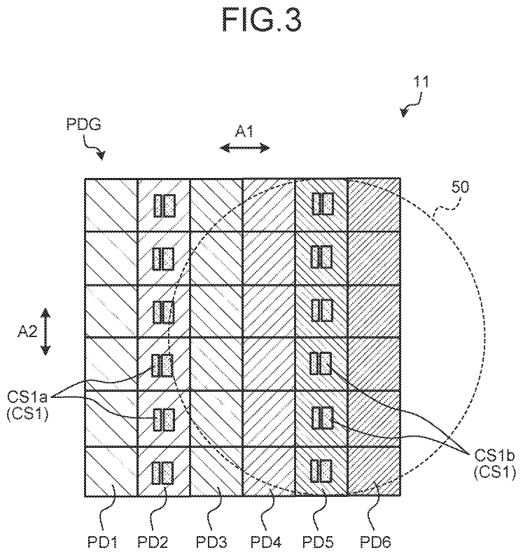

Next, a detailed configuration of the pixel array unit 10 is explained with reference to FIG. 2 to FIG. 5. FIG. 2 is a sectional view schematically illustrating structure of the pixel array unit 10 according to the embodiment of the present disclosure FIG. 3 is a plan view illustrating a configuration of a photodiode group PDG according to the embodiment of the present disclosure.

As illustrated in FIG. 2, the pixel array unit 10 includes a semiconductor layer 20, a color splitter layer 30, a prism layer 40, and a plurality of OCLs (on-chip lenses) 50. In the pixel array unit 10, the plurality of OCLs 50, the prism layer 40, the color splitter layer 30, and the semiconductor layer 20 are stacked in this order from a side on which the incident light L from the outside is made incident (hereinafter referred to as light incident side).

The semiconductor layer 20 includes a semiconductor region (not illustrated) of a first conductivity type (for example, P-type) and a plurality of semiconductor regions (not illustrated) of a second conductivity type (for example, N-type). In the semiconductor region of the first conductivity type, a plurality of semiconductor regions of the second conductivity type are formed side by side in a plane direction (an array direction of the pixels 11) in pixel units, whereby the photodiodes PD1 to PD6 by PN junctions are formed side by side in this order in a given direction A1.

The photodiodes PD1 to PD6 are an example of a photoelectric conversion unit. Note that, in the following explanation, the photodiodes PD1 to PD6 are collectively referred to as “photodiodes PD” as well.

In addition, in the photodiodes PD1 to PD6 (hereinafter referred to as “photodiode group PDG” as well) on which the incident light L is made incident via the same OCL 50, as illustrated in FIG. 3, a plurality of (six in the figure) each of photodiodes PD1 to PD6 are provided. That is, in each one pixel 11, a plurality of photodiodes PD1 to PD6 are provided.

All of the plurality of photodiodes PD1 to PD6 are disposed side by side in a given direction A2. Such a direction A2 is a direction substantially perpendicular to the direction A1.

The photodiode PD1 is, for example, a photoelectric conversion unit that receives and photoelectrically converts light in a violet wavelength region (hereinafter also referred to as “purple region”). The photodiode PD2 is, for example, a photoelectric conversion unit that receives and photoelectrically converts light in a blue wavelength region (hereinafter also referred to as “blue region”).

The photodiode PD3 is, for example, a photoelectric conversion unit that receives and photoelectrically converts light in a green wavelength region (hereinafter also referred to as a “green region”). The photodiode PD4 is, for example, a photoelectric conversion unit that receives and photoelectrically converts light in a yellow wavelength region (hereinafter also referred to as a “yellow region”).

The photodiode PD5 is, for example, a photoelectric conversion unit that receives and photoelectrically converts light in an orange wavelength region (hereinafter also referred to as “orange region”). The photodiode PD6 is, for example, a photoelectric conversion unit that receives and photoelectrically converts light in a red wavelength region (hereinafter also referred to as a “red region”).

Note that a not-illustrated wiring layer is disposed on the surface on the opposite side of the light incident side of the semiconductor layer 20. Such a wiring layer is configured by forming a plurality of wiring films (not illustrated) and a plurality of pixel transistors (not illustrated) in an interlayer insulating film (not illustrated). For example, such a plurality of pixel transistors reads electric charges accumulated in the photodiodes PD1 to PD6.

The color splitter layer 30 is disposed on the surface on the light incident side in the semiconductor layer 20. The color splitter layer 30 includes a low refractive index layer 31 and a plurality of high refractive index portions 32.

The low refractive index layer 31 is made of a material having a refractive index lower than that of the high refractive index portions 32. The low refractive index layer 31 is made of, for example, a metal oxide such as a silicon oxide or an aluminum oxide or an organic substance such as acrylic resin.

The high refractive index portions 32 having a predetermined shape are provided on the inside of the low refractive index layer 31. The high refractive index portions 32 are made of a material having a refractive index higher than that of the low refractive index layer 31. The high refractive index portions 32 are made of, for example, a silicon compound such as silicon nitride or silicon carbide, a metal oxide such as a titanium oxide, a tantalum oxide, a niobium oxide, a hafnium oxide, an indium oxide, or a tin oxide, or a composite oxide thereof. The high refractive index portions 32 may be made of an organic substance such as siloxane.

In the color splitter layer 30, a plurality of color splitters CS1 configured by the high refractive index portions 32 and the low refractive index layer 31 adjacent to such high refractive index portions 32 are disposed. Such a color splitter CS1 includes a color splitter CS1a and a color splitter CS1b.

The color splitter CS1a is disposed, for example, on the light incident side of the photodiode PD2. The color splitter CS1b is disposed, for example, on the light incident side of the photodiode PD5.

As illustrated in FIG. 3, in each one pixel 11, a plurality of (six in the figure) color splitters CS1a and a plurality of (six in the figure) CS1b are provided. All of the plurality of color splitters CS1a and the plurality of color splitters CS1b are disposed side by side in the given direction A2. Action and the like of the color splitter CS1 are explained below.

The prism layer 40 is disposed on the surface on the light incident side in the color splitter layer 30. The prism layer 40 includes a high refractive index layer 41 and a low refractive index layer 42. In the prism layer 40, the low refractive index layer 42 and the high refractive index layer 41 are stacked in order from the light incident side.

The high refractive index layer 41 is made of a material having a refractive index higher than that of the low refractive index layer 42. The high refractive index layer 41 is made of, for example, a silicon compound such as silicon nitride or silicon carbide, a metal oxide such as a titanium oxide, a tantalum oxide, a niobium oxide, a hafnium oxide, an indium oxide, or a tin oxide, or a composite oxide thereof. The high refractive index layer 41 may be made of an organic substance such as siloxane.

A convex portion 41a having a predetermined shape is provided on the surface on the light incident side in the high refractive index layer 41.

The low refractive index layer 42 is made of a material having a refractive index lower than that of the high refractive index layer 41. The low refractive index layer 42 is made of, for example, a metal oxide such as a silicon oxide or an aluminum oxide or an organic substance such as acrylic resin.

In the prism layer 40, a prism portion P configured by the convex portion 41a of the high refractive index layer 41 and the low refractive index layer 42 adjacent to such a convex portion 41a is disposed. Action and the like of such a prism portion P are explained below.

The OCL 50 is formed in, for example, a hemispherical shape and is provided for each of the pixels 11. The OCL 50 is a lens that condenses the incident light L on the prism portion P of each of the pixels 11. The OCL 50 is made of, for example, acrylic resin.

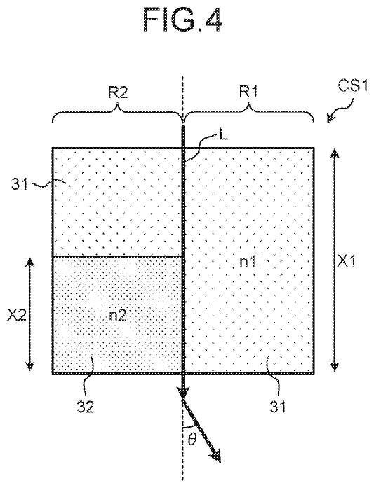

Subsequently, a principle of the color splitter CS1 according to the embodiment is explained with reference to FIG. 4. FIG. 4 is a diagram for explaining the principle of the color splitter CS1 according to the embodiment of the present disclosure.

As illustrated in FIG. 4, in the color splitter CS1, a first region R1 and a second region R2 differently disposed in the depth direction of the low refractive index layer 31 and the high refractive index portion 32 are disposed

Specifically, in the first region R1, the low refractive index layer 31 having a low refractive index (for example, a refractive index n1) is disposed in a light incident direction by length X1. In the second region R2, in addition to the low refractive index layer 31, the high refractive index portion 32 having a high refractive index (for example, a refractive index n2) is disposed in the light incident direction by length X2.

In the color splitter CS1 having such a configuration, when the incident light L is simultaneously made incident on the first region R1 and the second region R2, a difference occurs in a traveling distance of the incident light L between the first region R1 and the second region R2 because of a refractive index difference between the low refractive index layer 31 and the high refractive index portion 32.

Specifically, an optical path length D1 in the first region R1 is calculated by the following Expression (1).

$$D 1 = n 1 \times X 1 \qquad ( 1 )$$

An optical path length D2 in the second region R2 is calculated by the following Expression (2).

$$D 2 = n 1 \times ( X 1 - X 2 ) + n 2 \times X 2 \qquad ( 2 )$$

Based on Expressions (1) and (2), an optical path length difference ΔD between the first region R1 and the second region R2 is calculated by the following Expression (3).

$$Δ D = D 2 - D 1 = X 2 \times ( n 2 - n 1 ) \qquad ( 3 )$$

The incident light L having passed through the color splitter CS1 is emitted to be bent to the first region R1 side, to which light travels with a delay, as illustrated in FIG. 4 by the optical path length difference ΔD between the first region R1 and the second region R2.

A bending angle θ of such incident light L is calculated by the following Expression (4).

$$θ = arc tan ( Δ D / λ ) = arc tan ( X 2 \times ( n 2 - n 1 ) / λ ) \qquad ( 4 )$$

λ: wavelength of the incident light L

As shown in the above Expression (4), the bending angle θ of the incident light L depends on a wavelength λ of the incident light L. Therefore, by selecting the refractive indexes n1 and n2 of the low refractive index layer 31 and the high refractive index portion 32 as appropriate according to the respective wavelength regions, the color splitter CS1 can bend light in the respective wavelength regions in different desired directions.

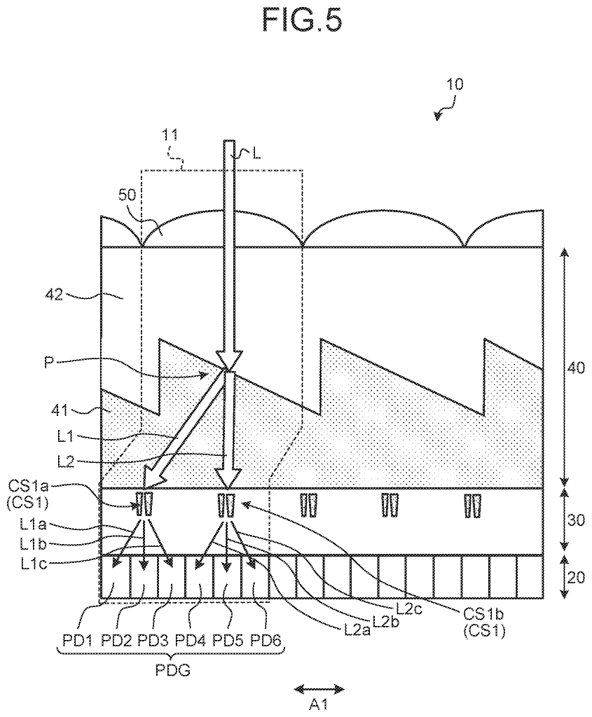

FIG. 5 is a diagram illustrating an incident state of the incident light L in the pixel array unit 10 according to the embodiment of the present disclosure. As illustrated in FIG. 5, the incident light L having all the wavelength regions in the visible region is condensed by the OCL 50 and reaches the prism portion P in the prism layer 40.

The prism portion P according to the embodiment splits such incident light L into light L1 in a short wavelength region (for example, a violet to green wavelength region) and light L2 in a long wavelength region (for example, a yellow to red wavelength region).

Further, the prism portion P according to the embodiment bends the light L1 in the short wavelength region toward the color splitter CS1a of the same pixel 11 and bends the light L2 in the long wavelength region toward the color splitter CS1b of the same pixel 11.

The color splitter CS1a splits the light L1 having reached the color splitter CS1a into light L1a of the purple region, light L1b of the blue region, and light L1c of the green region.

Further, the color splitter CS1a bends the light L1a in the purple region toward the photodiode PD1, bends the light L1b in the blue region toward the photodiode PD2, and bends the light L1c in the green region toward the photodiode PD3.

Similarly, the color splitter CS1b splits the light L2 having reached the color splitter CS1b into light L2a in the yellow region, light L2b in the orange region, and light L2c in the red region.

Further, the color splitter CS1b bends the light L2a in the yellow region toward the photodiode PD4, bends the light L2b in the orange region toward the photodiode PD5, and bends the light L2c in the red region toward the photodiode PD6.

As explained above, in the embodiment, since the prism portion P and the color splitter CS1 are disposed between the OCL 50 and the photodiodes PD1 to PD6, the lights L1a to L2c in the different wavelength regions can be respectively efficiently made incident on the photodiodes PD1 to PD6.

Consequently, in the embodiment, in one pixel 11, light in six different wavelength regions (that is, light of six colors) can be efficiently photoelectrically converted. Therefore, according to the embodiment, it is possible to improve the image quality of the pixel array unit 10.

In the embodiment, the prism portion P is desirably disposed further on the light incident side than the color splitter CS1. By disposing the prism portion P more suitable for the spectroscopy of light having a wide wavelength region (for example, the incident light L) on the light incident side in this way, the light L1a to L2c in the different wavelength regions can be respectively more efficiently made incident on the photodiodes PD1 to PD6.

Therefore, according to the embodiment, it is possible to further improve the image quality of the pixel array unit 10.

In the embodiment, the color splitter CS1 is desirably disposed between the prism portion P and the photodiodes PD1 to PD6 rather than the prism portion P. By using the color splitter CS1 that can split light having a limited wavelength region (for example, light L1 and light L2) with high resolution in this way, the light L1a to the light L2c in the different wavelength regions can be respectively more efficiently made incident on the photodiodes PD1 to PD6.

Therefore, according to the embodiment, it is possible to further improve the image quality of the pixel array unit 10.

In the embodiment, the color splitter CS1 desirably has meta-surface structure. Such meta-surface structure is structure in which a plurality of columnar portions formed in one color splitter CS1 is arrayed at a period equal to or less than the wavelength λ of the incident light L.

Consequently, since an effective refractive index of the color splitter CS1 can be changed, the light L1a to the light L2c in the different wavelength regions can be further bent in desired directions.

Therefore, according to the embodiment, it is possible to further improve the image quality of the pixel array unit 10.

In the embodiment, as illustrated in FIG. 3, it is desirable that a plurality of (for example, six) photodiodes PD on which light in the same wavelength region is made incident are provided in one pixel 11 and the plurality of photodiodes PD are disposed side by side in the given direction A2.

Consequently, since the pixel array unit 10 can be formed using a pattern regularly repeated in the direction A2, manufacturing cost of the pixel array unit 10 can be reduced.

Furthermore, in the embodiment, a plurality of color filters (not illustrated) corresponding to the respective wavelength regions may be disposed between the color splitter CS1 and the photodiodes PD1 to PD6.

By disposing the color filters having a spectral characteristic more excellent than that of the color splitter CS1 in this way, occurrence of color mixture in the photodiodes PD1 to PD6 can be suppressed.

### VARIOUS MODIFICATIONS

### Modification 1

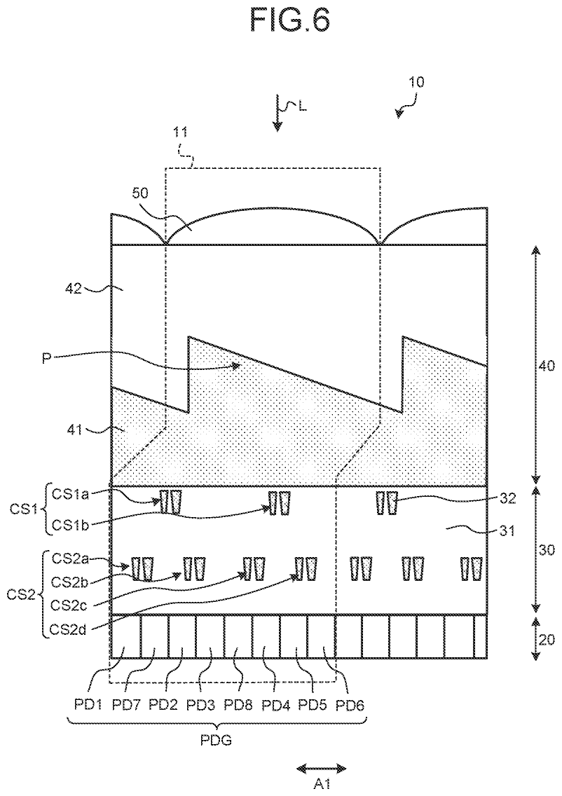

Subsequently, various modifications of the pixel array unit 10 according to the embodiment of the present disclosure are explained with reference to FIG. 6 to FIG. 18.

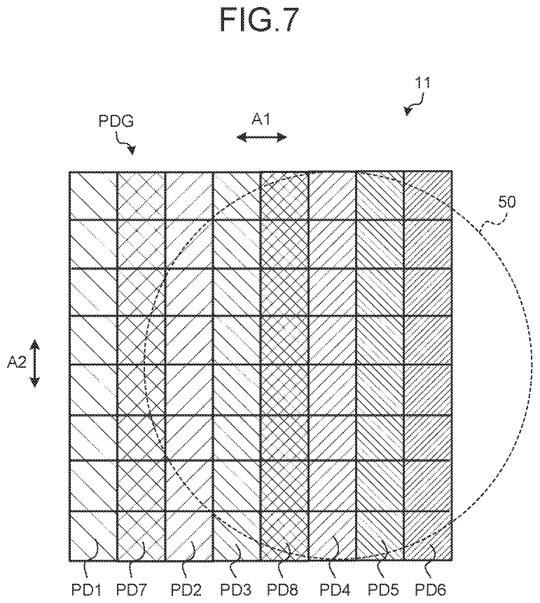

FIG. 6 is a sectional view schematically illustrating structure of the pixel array unit 10 according to a modification 1 of the embodiment of the present disclosure and is a view corresponding to FIG. 2 of the embodiment. FIG. 7 is a plan view illustrating a configuration of a photodiode group PDG according to the modification 1 of the embodiment of the present disclosure and is a view corresponding to FIG. 3 of the embodiment.

In the pixel array unit 10 according to the modification 1, the configuration of the photodiode group PDG and the configuration of the color splitter layer 30 are different from those in the embodiment. Specifically, as illustrated in FIG. 6, in the semiconductor layer 20, photodiodes PD1, PD7, PD2, PD3, PD8, PD4, PD5, and PD6 are formed side by side in this order in the given direction A1.

In each of the photodiodes PD1 to PD8 on which the incident light L is made incident via the same OCL 50, as illustrated in FIG. 7, a plurality of (in the figure, eight) photodiodes PD1 to PD8 are provided. That is, a plurality of photodiodes PD1 to PD8 are provided in each one pixel 11. All of the plurality of photodiodes PD1 to PD8 are disposed side by side in the given direction A2.

The photodiode PD7 is, for example, a photoelectric conversion unit that receives and photoelectrically converts light in a cyan wavelength region (hereinafter also referred to as “cyan region”). The photodiode PD8 is, for example, a photoelectric conversion unit that receives and photoelectrically converts light in a yellow-green wavelength region (hereinafter also referred to as “yellow-green region”).

Note that, since the photodiodes PD1 to PD6 are the photoelectric conversion units that receive and photoelectrically convert the light in the wavelength regions similar to those in the embodiment explained above, detailed explanation of the photodiodes PD1 to PD6 is omitted.

In the color splitter layer 30, a color splitter CS2 is disposed in addition to the color splitter CS1. The color splitter CS2 is an example of another color splitter.

Like the color splitter CS1, the color splitter CS2 is configured by the high refractive index portion 32 and the low refractive index layer 31 adjacent to the high refractive index portion 32. The color splitter CS2 is disposed between the color splitter CS1 and the photodiode group PDG. The color splitter CS2 includes color splitters CS2a to CS2d.

The color splitter CS2a is disposed, for example, on the light incident side of the boundary between the photodiode PD1 and the photodiode PD7. The color splitter CS2b is disposed, for example, on the light incident side of the boundary between the photodiode PD2 and the photodiode PD3.

The color splitter CS2c is disposed, for example, on the light incident side of the boundary between the photodiode PD8 and the photodiode PD4. The color splitter CS2d is disposed, for example, on the light incident side of the boundary between the photodiode PD5 and the photodiode PD6.

The color splitter CS1a of the color splitter CS1 is disposed, for example, on the light incident side of the boundary between the photodiode PD7 and the photodiode PD2. The color splitter CS1b is disposed, for example, on the light incident side of the boundary between the photodiode PD4 and the photodiode PD5.

Although not illustrated in FIG. 7, a plurality of (for example, eight) color splitters CS1a, CS1b, and CS2a to CS2d are provided in each one pixel 11. All of the plurality of color splitters CS1a, CS1b, and CS2a to CS2d are disposed side by side in the given direction A2.

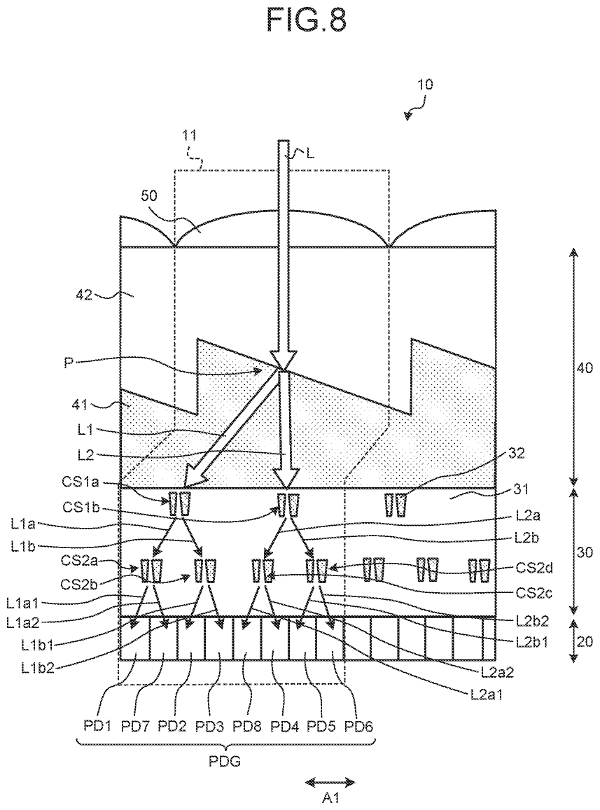

FIG. 8 is a diagram illustrating an incident state of the incident light L in the pixel array unit 10 according to the modification 1 of the embodiment of the present disclosure. As illustrated in FIG. 8, in the modification 1, the incident light L having all the wavelength regions in the visible region is condensed by the OCL 50 and reaches the prism portion P in the prism layer 40.

The prism portion P according to the modification 1 splits the incident light L into the light L1 in a short wavelength region (for example, a violet to green wavelength region) and the light L2 in a long wavelength region (for example, a yellow to red wavelength region).

Further, the prism portion P according to the modification 1 bends the light L1 in the short wavelength region toward the color splitter CS1a of the same pixel 11 and bends the light L2 in the long wavelength region toward the color splitter CS1b of the same pixel 11.

The color splitter CS1a splits the light L1 having reached the color splitter CS1a into the light L1a in a short wavelength region (for example, a violet to cyan wavelength region) and the light L1b in a long wavelength region (for example, a blue to green wavelength region).

Further, the color splitter CS1a bends the light L1a in the short wavelength region toward the color splitter CS2a and bends the light L1b in the long wavelength region toward the color splitter CS2b.

Similarly, the color splitter CS1b splits the light L2 having reached the color splitter CS1b into the light L2a in a short wavelength region (for example, a yellow-green to green wavelength region) and the light L2b in a long wavelength region (for example, an orange to red wavelength region).

Further, the color splitter CS1b bends the light L2a in the short wavelength region toward the color splitter CS2c and bends the light L2b in the long wavelength region toward the color splitter CS2d.

The color splitter CS2a splits the light L1a having reached the color splitter CS2a into light L1a1 in the purple region and light L1a2 in the cyan region. Further, the color splitter CS2a bends the light L1a1 in the purple region toward the photodiode PD1 and bends the light L1a2 in the cyan region toward the photodiode PD7.

Similarly, the color splitter CS2b splits the light L1b having reached the color splitter CS2b into the light L1b1 in the blue region and the light L1b2 in the green region. Further, the color splitter CS2b bends the light L1b1 in the blue region toward the photodiode PD2 and bends the light L1b2 in the green region toward the photodiode PD3.

The color splitter CS2c splits the light L2a having reached the color splitter CS2c into light L2a1 in the yellow-green region and light L2a2 in the green region. Further, the color splitter CS2c bends the light L2a1 in the yellow-green region toward the photodiode PD8 and bends the light L2a2 in the green region toward the photodiode PD4.

The color splitter CS2d splits the light L2b reaching the color splitter CS2d into the light L2b1 in the orange region and the light L2b2 in the red region. Further, the color splitter CS2d bends the light L2b1 in the orange region toward the photodiode PD5, and bends the light L2b2 in the red region toward the photodiode PD6.

As described above, in the modification 1, since the prism portion P and the color splitters CS1 and CS2 are disposed between the OCL 50 and the photodiodes PD1 to PD8, the lights L1a1 to L2b2 in the different wavelength regions can be efficiently made incident on the photodiodes PD1 to PD8.

Consequently, in the modification 1, in one pixel 11, light in eight different wavelength regions (that is, light of eight colors) can be efficiently photoelectrically converted. Therefore, according to the modification 1, it is possible to improve the image quality of the pixel array unit 10.

In the modification 1, the color splitter CS2 desirably has a meta-surface structure. Consequently, since an effective refractive index of the color splitter CS2 can be changed, the light beams L1a1 to L2b2 in different wavelength regions can be further respectively bent in desired directions.

Therefore, according to the modification 1, it is possible to further improve the image quality of the pixel array unit 10.

In the modification 1, a plurality of color filters (not illustrated) corresponding to the respective wavelength regions may be disposed between the color splitter CS2 and the photodiodes PD1 to PD8.

By disposing the color filters having a spectral characteristic more excellent than that of the color splitter CS1 in this way, occurrence of color mixture in the photodiodes PD1 to PD8 can be suppressed.

### Modification 2

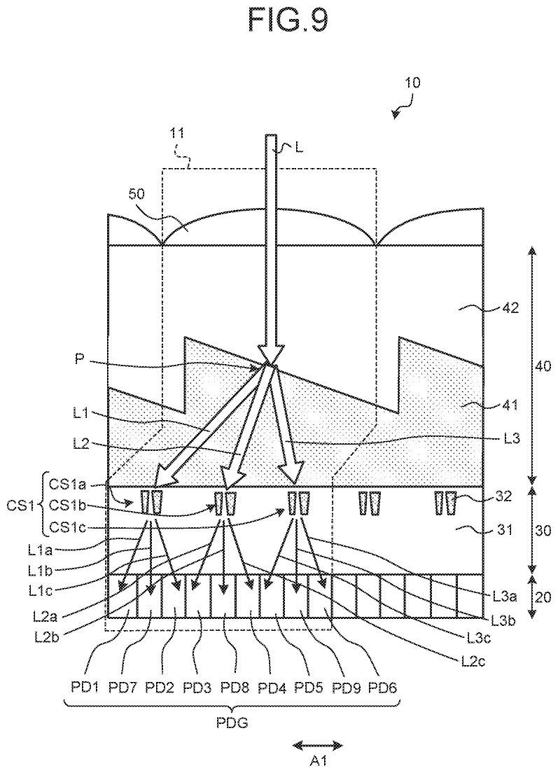

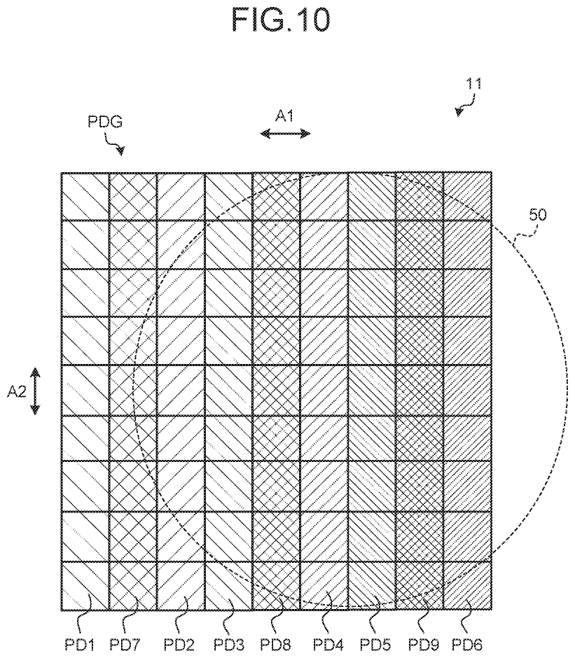

FIG. 9 is a diagram illustrating a configuration of the pixel array unit 10 and an incident state of the incident light L according to a modification 2 of the embodiment of the present disclosure and is a diagram corresponding to FIG. 5 of the embodiment. FIG. 10 is a plan view illustrating a configuration of the photodiode group PDG according to a modification 2 of the embodiment of the present disclosure and is a diagram corresponding to FIG. 3 of the embodiment.

In the pixel array unit 10 according to the modification 2, a configuration of the color splitter layer 30 and a function of the prism portion P are different from those in the embodiment. Specifically, as illustrated in FIG. 9, in the semiconductor layer 20, photodiodes PD1, PD7, PD2, PD3, PD8, PD4, PD5, PD9, and PD6 are formed in this order in the given direction A1.

In each of the photodiodes PD1 to PD9 on which the incident light L is made incident via the same OCL 50, as illustrated in FIG. 10, a plurality of (in the figure, nine) photodiodes PD1 to PD9 are provided. That is, a plurality of photodiodes PD1 to PD9 are provided in each one pixel 11. All of the plurality of photodiodes PD1 to PD9 are disposed side by side in the given direction A2.

The photodiode PD9 is, for example, a photoelectric conversion unit that receives and photoelectrically converts light in a red-orange wavelength region (hereinafter also referred to as “red-orange region”). Note that, since the photodiodes PD1 to PD8 are photoelectric conversion units that receive and photoelectrically convert light in wavelength regions similar to that in the embodiment and the modification 1, detailed explanation of the photodiodes PD1 to PD8 is omitted.

As illustrated in FIG. 9, a color splitter CS1 having a configuration different from that in the embodiment is provided in the color splitter layer 30. Specifically, the color splitter CS1 includes color splitters CS1a, CS1b, and CS1c.

The color splitter CS1a is disposed, for example, on the light incident side of the photodiode PD7. The color splitter CS1b is disposed, for example, on the light incident side of the photodiode PD8. The color splitter CS1c is disposed, for example, on the light incident side of the photodiode PD9.

Although not illustrated in FIG. 10, a plurality of for example, nine) color splitters CS1a to CS1c are provided in each one pixel 11. All of the plurality of color splitters CS1a to CS1c are disposed side by side in the given direction A2.

As illustrated in FIG. 9, in the modification 2, the incident light L having all the wavelength regions in the visible region is condensed by the OCL 50 and reaches the prism portion P in the prism layer 40.

The prism portion P according to the second modification splits the incident light L into the light L1 in a short wavelength region (for example, a violet to blue wavelength region), the light L2 in a middle wavelength region (for example, a green to yellow wavelength region), and light L3 in a long wavelength region (for example, an orange to red wavelength region).

Further, the prism portion P according to the modification 2 bends the light L1 in the short wavelength region toward the color splitter CS1a of the same pixel 11 and bends the light L2 in the middle wavelength region toward the color splitter CS1b of the same pixel 11. The prism portion P according to the modification 2 bends the light L3 in the long wavelength region toward the color splitter CS1c of the same pixel 11.

The color splitter CS1a splits the light L1 having reached the color splitter CS1a into the light L1a in the purple region, the light L1b in the cyan region, and the light L1c in the blue region.

Further, the color splitter CS1a bends the light L1a in the purple region toward the photodiode PD1, bends the light L1b in the cyan region toward the photodiode PD7, and bends the light L1c in the blue region toward the photodiode PD2.

Similarly, the color splitter CS1b splits the light L2 having reached the color splitter CS1b into the light L2a in the green region, the light L2b in the yellow-green region, and the light L2c in the yellow region.

Further, the color splitter CS1b bends the light L2a in the green region toward the photodiode PD3, bends the light L2b in the yellow-green region toward the photodiode PD8, and bends the light L2c in the yellow region toward the photodiode PD4.

The color splitter CS1c splits the light L3 having reached the color splitter CS1c into light L3a in the orange region, light L3b in the red-orange region, and light L3c in the red region.

Further, the color splitter CS1c bends the light L3a in the orange region toward the photodiode PD5, bends the light L3b in the red-orange region toward the photodiode PD9, and bends the light L3c in the red region toward the photodiode PD6.

As explained above, in the second modification, the incident light L is split into three types of light in the different wavelength regions by the prism portion P and the three types of light in the different wavelength regions are made incident on the three color splitters CS1a to CS1c. Consequently, in the modification 2, the light L1a to the light L3c in the different wavelength regions can be efficiently made incident on the photodiodes PD1 to PD9.

That is, in the modification 2, in each one pixel 11, the light in the nine different wavelength regions (that is, light of nine colors) can be efficiently photoelectrically converted. Therefore, according to the modification 2, it is possible to improve the image quality of the pixel array unit 10.

In the modification 2, a plurality of color filters (not illustrated) corresponding to the respective wavelength regions may be disposed between the color splitter CS1 and the photodiodes PD1 to PD9.

By disposing the color filters having the spectral characteristics more excellent than that of the color splitter CS1, occurrence of color mixture in the photodiodes PD1 to PD9 can be suppressed.

### Modification 3

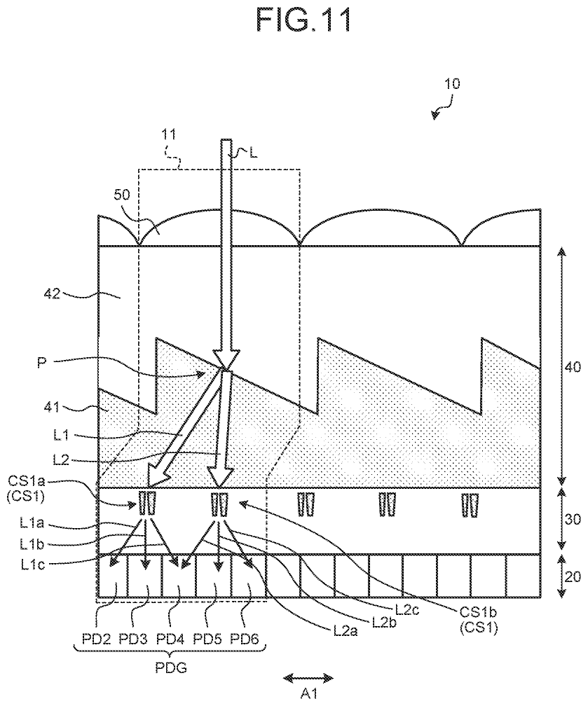

FIG. 11 is a diagram illustrating a configuration of the pixel array unit 10 and an incident state of the incident light L according to a modification 3 of the embodiment of the present disclosure and is a diagram corresponding to FIG. 5 of the embodiment.

In the pixel array unit 10 according to the modification 3, a configuration of the photodiode group PDG and a function of the color splitter layer 30 are different from those in the embodiment. Specifically, as illustrated in FIG. 11, in the semiconductor layer 20, the photodiodes PD2 to PD6 are formed side by side in this order in the given direction A1.

Although not illustrated, in the photodiodes PD2 to PD6 on which the incident light L is made incident via the same OCL 50, a plurality of (for example, five) photodiodes PD2 to PD6 are provided. That is, a plurality of photodiodes PD2 to PD6 are provided in each one pixel 11.

All of the plurality of photodiodes PD2 to PD6 are disposed side by side in the given direction A2 (see FIG. 3). Note that, since the photodiodes PD2 to PD6 are photoelectric conversion units that receive and photoelectrically convert light in the same wavelength regions as those in the embodiment explained above, detailed explanation of the photodiodes PD2 to PD6 is omitted.

The color splitter CS1 in the modification 3 includes the color splitters CS1a and CS1b. The color splitter CS1a is disposed, for example, on the light incident side of the photodiode PD3. The color splitter CS1b is disposed, for example, on the light incident side of the photodiode PD5.

A plurality of (for example, five) color splitters CS1a and CS1b are provided in each one pixel 11. All of the plurality of color splitters CS1a and CS1b are disposed side by side in the given direction A2.

As illustrated in FIG. 11, in a modification 3, the incident light L having all the wavelength regions in the visible region is condensed by the OCL 50 and reaches the prism portion P in the prism layer 40.

The prism portion P according to the modification 3 splits the incident light L into the light L1 in a short wavelength region (for example, a blue to yellow wavelength region) and the light L2 in a long wavelength region (for example, a yellow to red wavelength region).

Further, the prism portion P according to the modification 3 bends the light L1 in the short wavelength region toward the color splitter CS1a of the same pixel 11 and bends the light L2 in the long wavelength region toward the color splitter CS1b of the same pixel 11.

The color splitter CS1a splits the light L1 having reached the color splitter CS1a into the light L1a in the blue region, the light L1b in the green region, and the light L1c in the yellow region.

Further, the color splitter CS1a bends the light L1a in the blue region toward the photodiode PD2, bends the light L1b in the green region toward the photodiode PD3, and bends the light L1c in the yellow region toward the photodiode PD4.

Similarly, the color splitter CS1b splits the light L2 having reached the color splitter CS1b into light L2a in the yellow region, light L2b in the orange region, and light L2c in the red region.

Further, the color splitter CS1b bends the light L2a in the yellow region toward the photodiode PD4, bends the light L2b in the orange region toward the photodiode PD5, and bends the light L2c in the red region toward the photodiode PD6.

As explained above, in the modification 3, in each one pixel 11, light in five different wavelength regions (that is, light of five colors) can be efficiently photoelectrically converted. Therefore, the image quality of the pixel array unit 10 can be improved.

In the modification 3, a pair of color splitters CS1a and CS1b adjacent to each other makes light in the same wavelength region (here, light in the yellow region) incident on the same photodiode PD4.

Consequently, more light in a specific wavelength region can be made incident on the photodiode PD. Therefore, according to the modification 3, the image quality of the pixel array unit 10 can be further improved.

Note that, in the example illustrated in FIG. 11, an example is explained in which light in the same wavelength region is made incident on the same photodiode PD from a pair of color splitters CS1a and CS1b adjacent to each other based on the configuration of the embodiment explained above (FIG. 2 and the like). However, the present disclosure is not limited to such an example.

For example, in the present disclosure, light in the same wavelength region may be made incident on the same photodiode PD from a pair of color splitters CS2 or the like adjacent to each other based on the configuration of the modification 1 (FIG. 6 and the like). Further, in the present disclosure, light in the same wavelength region may be made incident on the same photodiode PD from a pair of color splitters CS1 adjacent to each other based on the configuration of the modification 2 (FIG. 9 and the like).

### Modification 4

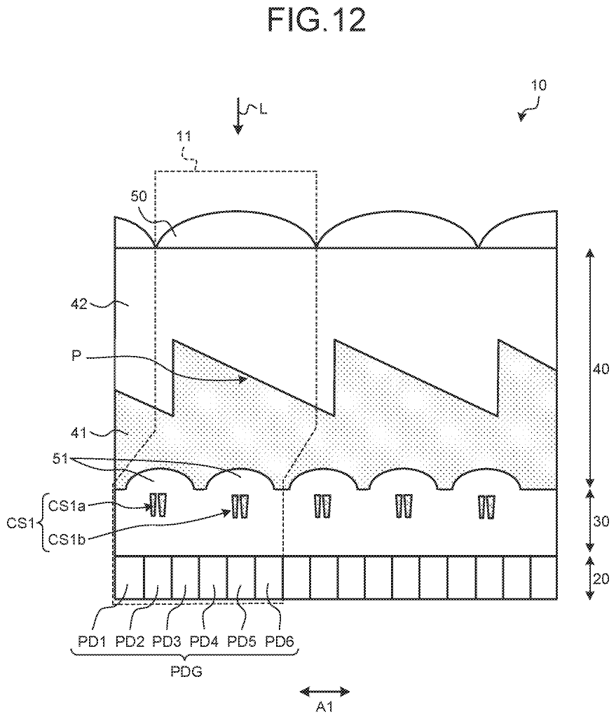

FIG. 12 is a sectional view schematically illustrating structure of the pixel array unit 10 according to a modification 4 of the embodiment of the present disclosure. As illustrated in FIG. 12, in the modification 4, a plurality of hemispherical microlenses 51 are provided between the prism portion P and the color splitter CS1.

The plurality of microlenses 51 are respectively disposed, for example, on the light incident side of the color splitters CS1a and CS1b. Then, the plurality of microlenses 51 condense the light L1 and the light L2 (see FIG. 5) made incident on the color splitters CS1a and CS1b toward the color splitters CS1a and CS1b.

Consequently, since light amounts of the light L1 and the light L2 made incident on the color splitters CS1a and CS1b can be increased, the sensitivity of the photodiodes PD1 to PD6 can be improved.

Note that the microlenses 51 are not limited to a hemispherical lens and may be a meta-lens having a meta-surface structure. This also makes it possible to improve the sensitivity of the photodiodes PD1 to PD6.

### Modification 5

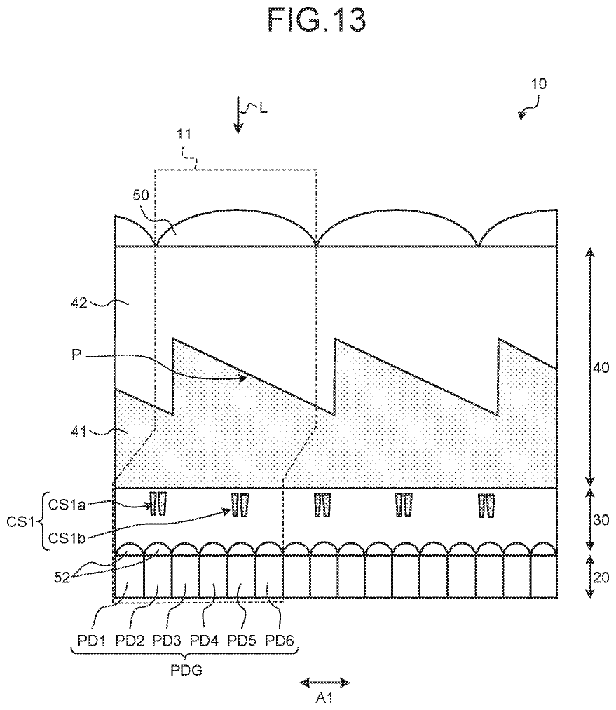

FIG. 13 is a sectional view schematically illustrating structure of the pixel array unit 10 according to a modification 5 of the embodiment of the present disclosure. As illustrated in FIG. 13, in the modification 5, a plurality of microlenses 52 are provided between the color splitter CS1 and the photodiode group PDG.

The plurality of microlenses 52 are respectively disposed, for example, on the light incident side of the photodiodes PD1 to PD6. The plurality of microlenses 52 condenses the lights L1a to L2c (see FIG. 5) made incident on the photodiodes PD1 to PD6 toward the photodiodes PD1 to PD6.

Consequently, a light amount of the light L1a to the light L2c made incident on the photodiodes PD1 to PD6 can be increased. Therefore, the sensitivity of the photodiodes PD1 to PD6 can be improved.

The microlenses 52 are not limited to a hemispherical lens and may be a meta-lens having a meta-surface structure. This also makes it possible to improve the sensitivity of the photodiodes PD1 to PD6.

### Modification 6

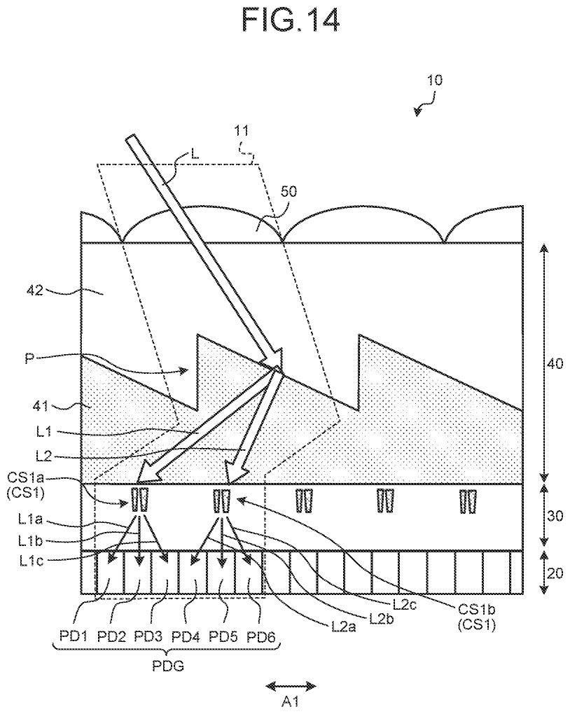

FIG. 14 is a sectional view schematically illustrating structure of the pixel array unit 10 according to a modification 6 of the embodiment of the present disclosure. As illustrated in FIG. 14, a relative positional relation among the OCL 50, the prism portion P, and the color splitter CS1 in the pixels 11 may be adjusted according to, for example, the distance (image height) from the center of the pixel array unit 10 (so-called pupil correction).

Consequently, in the pixels 11 respectively having different image heights in the pixel array unit 10, the light L1a to the light L2c can be substantially uniformly made incident on the photodiodes PD1 to PD6. Therefore, according to the modification 6, the image quality of the pixel array unit 10 can be further improved.

### Modification 7

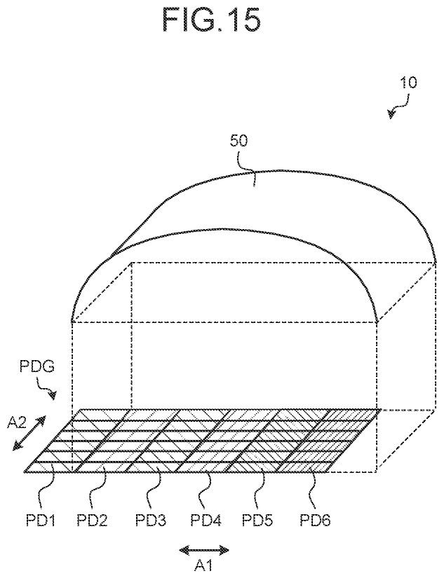

FIG. 15 is a perspective view schematically illustrating structure of the pixel array unit 10 according to a modification 7 of the embodiment of the present disclosure. Note that, in FIG. 15, components other than the OCL 50 and the photodiode group PDG are not illustrated for facilitate understanding.

As illustrated in FIG. 15, in the modification 7, the OCL 50 is not a hemispherical lens but a semi-cylindrical lens structure (a so-called cylinder lens structure). Then, in the modification 7, the axial direction of the OCL 50 having the cylinder lens structure is directed in the same direction as the direction A2 in which the plurality of photodiodes PD (for example, photodiodes PD1) on which light in the same wavelength region is made incident are disposed side by side.

Consequently, light can be substantially uniformly made incident on the plurality of photodiodes PD on which light in the same wavelength region is made incident. Therefore, according to the modification 7, the image quality of the pixel array unit 10 can be further improved.

### Modifications 8 and 9

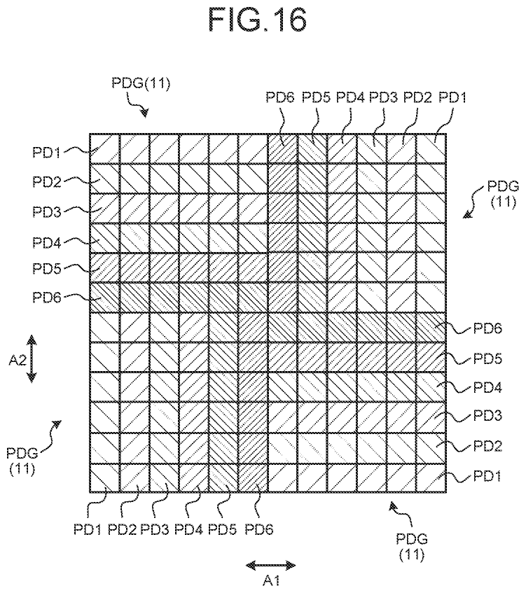

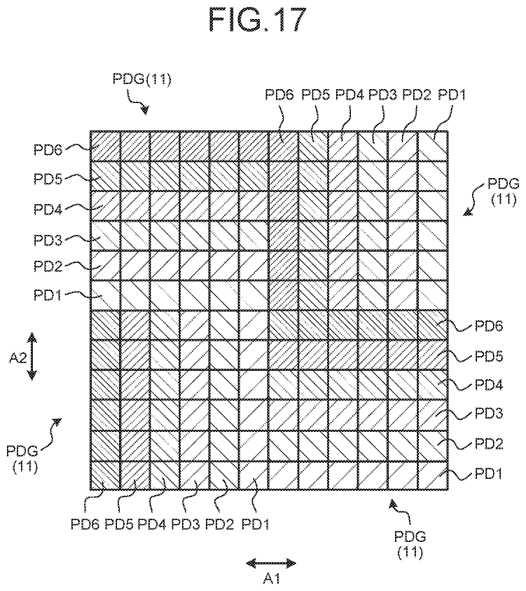

FIG. 16 and FIG. 17 are plan views illustrating an example of disposition of a plurality of photodiode groups PDG according to modifications 8 and 9 of the embodiment of the present disclosure. As illustrated in FIG. 16, in the modification 8, in the photodiode groups PDG adjacent to each other, directions in which a plurality of photodiodes PD on which light in the same wavelength region is made incident are disposed side by side are different from each other.

For example, as illustrated in FIG. 16, in the photodiode groups PDG located at the upper right and the lower left, a plurality of photodiodes PD on which light in the same wavelength region is made incident are disposed side by side in the direction A2. On the other hand, in the photodiode groups PDG located at the upper left and the lower right, a plurality of photodiodes PD on which light in the same wavelength region is made incident are disposed side by side in the direction A1.

Consequently, it is possible to suppress occurrence of color unevenness due to localization of array of the photodiodes PD in the photodiode group PDG adjacent to each other. Therefore, according to the modification 8, the image quality of the pixel array unit 10 can be further improved.

Note that an array example of the photodiode groups PDG adjacent to each other is not limited to the example illustrated in FIG. 16 and, for example, the array may be changed as illustrated in FIG. 17. This also makes it possible to further improve the image quality of the pixel array unit 10.

### Modification 10

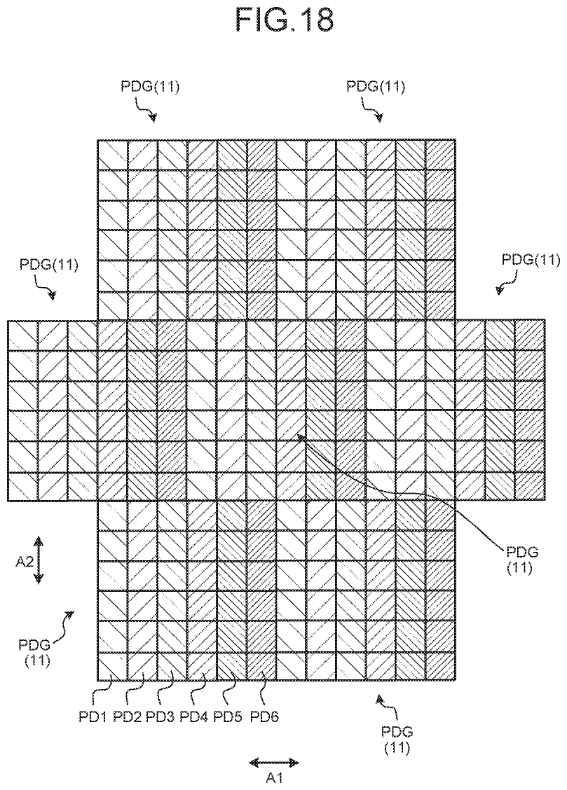

FIG. 18 is a plan view illustrating an example of disposition of a plurality of photodiode groups PDG according to a modification 10 of the embodiment of the present disclosure. As illustrated in FIG. 18, the plurality of photodiode groups PDG (that is, a plurality of pixels 11) may be arrayed in a staggered manner.

This also makes it possible to improve the image quality of the pixel array unit 10 because the prism portion P (see FIG. 2) and the color splitter CS1 (see FIG. 2) are disposed between the photodiode group PDG and the OCL 50 (see FIG. 2).

### Effects

The solid-state imaging element 1 according to the embodiment includes the plurality of photoelectric conversion units (photodiodes PD), the on-chip lens (the OCL 50), the prism portion P, and the plurality of color splitters CS1. The plurality of photoelectric conversion units (photodiodes PD) are disposed side by side in a matrix form in the semiconductor layer 20. The on-chip lens (the OCL 50) is disposed further on the light incident side than the semiconductor layer 20 to be shared by the plurality of photoelectric conversion units (photodiodes PD). The prism portion P is disposed between the on-chip lens (OCL 50) and the plurality of photoelectric conversion units (photodiodes PD). The plurality of color splitters CS1 are disposed between the prism portion P and the plurality of photoelectric conversion units (photodiodes PD).

This makes it possible to improve the image quality of the pixel array unit 10.

In the solid-state imaging element 1 according to the embodiment, the color splitter CS1 has meta-surface structure.

This makes it possible to further improve the image quality of the pixel array unit 10.

The solid-state imaging element 1 according to the embodiment further includes another color splitter (a color splitter CS2) disposed between the color splitter CS1 and the plurality of photoelectric conversion units (photodiodes PD).

This makes it possible to improve the image quality of the pixel array unit 10.

In the solid-state imaging element 1 according to the embodiment, light in the same wavelength region is made incident on a part of the photoelectric conversion units (photodiodes PD). The plurality of photoelectric conversion units (photodiodes PD) on which light in the same wavelength region is made incident are disposed side by side in the given direction A2.

This makes it possible to reduce manufacturing cost of the pixel array unit 10.

In the solid-state imaging element 1 according to the embodiment, the on-chip lens (the OCL 50) has cylinder lens structure having an axial direction in the same direction as the given direction A2.

This makes it possible to further improve the image quality of the pixel array unit 10.

The solid-state imaging element 1 according to the embodiment further includes a plurality of microlenses 51 and 52 disposed between the prism portion P and the plurality of photoelectric conversion units (photodiodes PD).

This makes it possible to improve the sensitivity of the photodiode PD.

In the solid-state imaging element 1 according to the embodiment, the pair of color splitters CS1a and CS1b adjacent to each other makes light in the same wavelength region incident on the same photoelectric conversion unit (photodiode PD).

This makes it possible to further improve the image quality of the pixel array unit 10.

The solid-state imaging element 1 according to the embodiment includes the plurality of photoelectric conversion units (photodiodes PD) and the on-chip lens (the OCL 50). The plurality of photoelectric conversion units (photodiodes PD) are disposed side by side in a matrix form in the semiconductor layer 20. The on-chip lens (the OCL 50) is disposed further on the light incident side than the semiconductor layer 20 to be shared by the plurality of photoelectric conversion units (photodiodes PD). The plurality of photoelectric conversion units (photodiodes PD) sharing one on-chip lens (OCL 50) respectively receive light in five or more different wavelength regions.

This makes it possible to improve the image quality of the pixel array unit 10.

### Electronic Equipment

Note that the present disclosure is not limited to the application to the solid-state imaging element. That is, the present disclosure is applicable to, besides the solid-state imaging element, all kinds of electronic equipment including solid-state imaging elements such as a camera module, an imaging device, a mobile terminal device having an imaging function, or a copying machine using a solid-state imaging element in an image reading section.

Examples of such an imaging device include a digital still camera and a video camera. Examples of such a portable terminal device having the imaging function include a smartphone and a tablet terminal.

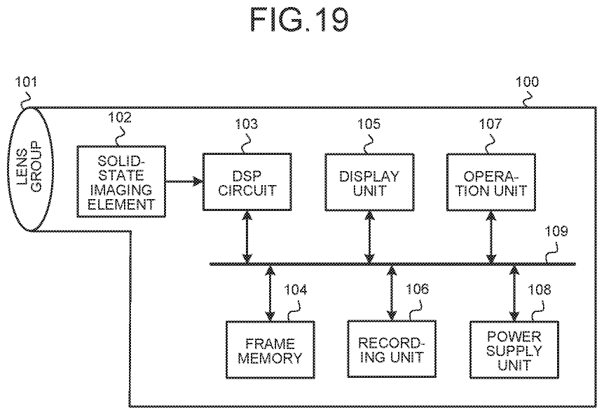

FIG. 19 is a block diagram illustrating a configuration example of an imaging device functioning as a electronic equipment 100 to which the technique according to the present disclosure is applied. The electronic equipment 100 illustrated in FIG. 19 is, for example, electronic equipment such as an imaging device such as a digital still camera or a video camera or a portable terminal device such as a smartphone or a tablet terminal.

In FIG. 19, the electronic equipment 100 includes a lens group 101, a solid-state imaging element 102, a DSP circuit 103, a frame memory 104, a display unit 105, a recording unit 106, an operation unit 107, and a power supply unit 108.

In the electronic equipment 100, the DSP circuit 103, the frame memory 104, the display unit 105, the recording unit 106, the operation unit 107, and the power supply unit 108 are connected to one another via a bus line 109.

The lens group 101 captures incident light (image light) from a subject and forms an image on an imaging surface of the solid-state imaging element 102. The solid-state imaging element 102 corresponds to the solid-state imaging element 1 according to the embodiment explained above and converts a light amount of the incident light imaged on the imaging surface by the lens group 101 into an electrical signal in units of pixels and outputs the electrical signal as a pixel signal.

The DSP circuit 103 is a camera signal processing circuit that processes a signal supplied from the solid-state imaging element 102. The frame memory 104 temporarily retains, in units of frames, the image data processed by the DSP circuit 103.

The display unit 105 includes, for example, a panel type display device such as a liquid crystal panel or an organic EL (Electro Luminescence) panel and displays a moving image or a still image captured by the solid-state imaging element 102. The recording unit 106 records image data of the moving image or the still image captured by the solid-state imaging element 102 on a recording medium such as a semiconductor memory or a hard disk.

The operation unit 107 issues operation commands for various functions of the electronic equipment 100 according to operation by a user. The power supply unit 108 supplies, as appropriate, various power sources serving as operation power sources for the DSP circuit 103, the frame memory 104, the display unit 105, the recording unit 106, and the operation unit 107 to these supply targets.

In the electronic equipment 100 configured as explained above, the image quality of the pixel array unit 10 can be improved by applying the solid-state imaging element 1 in the embodiments explained above as the solid-state imaging element 102.

Although the embodiments of the present disclosure are explained above, the technical scope of the present disclosure is not limited to the embodiments explained above per se. Various changes are possible without departing from the gist of the present disclosure. Components in different embodiments and modifications may be combined as appropriate.

The effects described in the present specification are only examples and are not limited. There may be other effects.

Note that the present technique can also take the following configurations.

(1)

A solid-state imaging element comprising:
a plurality of photoelectric conversion units disposed side by side in a matrix form in a semiconductor layer;
an on-chip lens disposed further on a light incident side than the semiconductor layer to be shared by the plurality of photoelectric conversion units;
a prism portion disposed between the on-chip lens and the plurality of photoelectric conversion units; and
a plurality of color splitters disposed between the prism portion and the plurality of photoelectric conversion units.

(2)

The solid-state imaging element according to the above (1), wherein
the color splitter has a meta-surface structure.

(3)

The solid-state imaging element according to the above (1) or (2), further comprising another color splitter disposed between the color splitter and the plurality of photoelectric conversion units.

(4)

The solid-state imaging element according to any one of the above (1) to (3), wherein
light in a same wavelength region is made incident on a part of the photoelectric conversion units, and
the plurality of photoelectric conversion units on which the light in the same wavelength region is made incident are disposed side by side along a given direction.

(5)

The solid-state imaging element according to the above (4), wherein
the on-chip lens has a cylinder lens structure having an axial direction in a same direction as the given direction.

(6)

The solid-state imaging element according to any one of the above (1) to (5), further comprising a plurality of microlenses disposed between the prism portion and the plurality of photoelectric conversion units.

(7)

The solid-state imaging element according to any one of the above (1) to (6), wherein
a pair of the color splitters adjacent to each other makes light in a same wavelength region incident on same one of the photoelectric conversion units.

(8)

The solid-state imaging element according to any one of the above (1) to (7), wherein
the plurality of photoelectric conversion units sharing one on-chip lens respectively receive light in five or more different wavelength regions.

(9)

A solid-state imaging element comprising:
a plurality of photoelectric conversion units disposed side by side in a matrix form in a semiconductor layer; and
an on-chip lens disposed further on a light incident side than the semiconductor layer to be shared by the plurality of photoelectric conversion units, wherein
the plurality of photoelectric conversion units sharing one on-chip lens respectively receive light in five or more different wavelength regions.

(10)

Electronic equipment comprising:
a solid-state imaging element;
an optical system that captures incident light from a subject and forms an image on an imaging surface of the solid-state imaging element; and
a signal processing circuit that performs processing on an output signal from the solid-state imaging element, wherein
the solid-state imaging element includes:
a plurality of photoelectric conversion units disposed side by side in a matrix form in a semiconductor layer;
an on-chip lens disposed further on a light incident side than the semiconductor layer to be shared by the plurality of photoelectric conversion units;
a prism portion disposed between the on-chip lens and the plurality of photoelectric conversion units; and
a plurality of color splitters disposed between the prism portion and the plurality of photoelectric conversion units.

(11)

The electronic equipment according to the above (10), wherein
the color splitter has a meta-surface structure.

(12)

The electronic equipment according to the above (10) or (11), wherein
the solid-state imaging element includes another color splitter disposed between the color splitter and the plurality of photoelectric conversion units.

(13)

The electronic equipment according to any one of the above (10) to (12), wherein
light in a same wavelength region is made incident on a part of the photoelectric conversion units, and
the plurality of photoelectric conversion units on which the light in the same wavelength region is made incident are disposed side by side in a given direction.

(14)

The electronic equipment according to the above (13), wherein
the on-chip lens has a cylinder lens structure having an axial direction in a same direction as the given direction.

(15)

The electronic equipment according to any one of the above (10) to (14), wherein
the solid-state imaging element includes a plurality of microlenses disposed between the prism portion and the plurality of photoelectric conversion units.

(16)

The electronic equipment according to any one of the above (10) to (15), wherein
a pair of the color splitters adjacent to each other makes light in a same wavelength region incident on same one of the photoelectric conversion units.

(17)

The electronic equipment according to any one of the above (10) to (16), wherein
a plurality of photoelectric conversion units sharing one on-chip lens respectively receive light in five or more different wavelength regions.

(18)

Electronic equipment comprising:
a solid-state imaging element;
an optical system that captures incident light from a subject and forms an image on an imaging surface of the solid-state imaging element; and
a signal processing circuit that performs processing on an output signal from the solid-state imaging element, wherein
the solid-state imaging element includes:
a plurality of photoelectric conversion units disposed side by side in a matrix form in a semiconductor layer; and
an on-chip lens disposed further on a light incident side than the semiconductor layer to be shared by the plurality of photoelectric conversion units, and
the plurality of photoelectric conversion units sharing one on-chip lens respectively receive light in five or more different wavelength regions.

### REFERENCE SIGNS LIST

1 SOLID-STATE IMAGING ELEMENT
10 PIXEL ARRAY UNIT
30 COLOR SPLITTER LAYER
40 PRISM LAYER
50 OCL
51, 52 MICROLENS
100 ELECTRONIC EQUIPMENT
CS1, CS1a, CS1b COLOR SPLITTER
CS2, CS2a to CS2d COLOR SPLITTER (EXAMPLE OF ANOTHER COLOR SPLITTER)
A2 DIRECTION (EXAMPLE OF GIVEN DIRECTION)
P PRISM PORTION
PD, PD1 to PD9 PHOTODIODE (EXAMPLE OF PHOTOELECTRIC CONVERSION UNIT)

1. A solid-state imaging element comprising:
a plurality of photoelectric conversion units disposed side by side in a matrix form in a semiconductor layer;
an on-chip lens disposed further on a light incident side than the semiconductor layer to be shared by the plurality of photoelectric conversion units;
a prism portion disposed between the on-chip lens and the plurality of photoelectric conversion units; and
a plurality of color splitters disposed between the prism portion and the plurality of photoelectric conversion units.

2. The solid-state imaging element according to claim 1, wherein
the color splitter has a meta-surface structure.

3. The solid-state imaging element according to claim 1, further comprising another color splitter disposed between the color splitter and the plurality of photoelectric conversion units.

4. The solid-state imaging element according to claim 1, wherein
light in a same wavelength region is made incident on a part of the photoelectric conversion units, and
the plurality of photoelectric conversion units on which the light in the same wavelength region is made incident are disposed side by side along a given direction.

5. The solid-state imaging element according to claim 4, wherein
the on-chip lens has a cylinder lens structure having an axial direction in a same direction as the given direction.

6. The solid-state imaging element according to claim 1, further comprising a plurality of microlenses disposed between the prism portion and the plurality of photoelectric conversion units.

7. The solid-state imaging element according to claim 1, wherein
a pair of the color splitters adjacent to each other makes light in a same wavelength region incident on same one of the photoelectric conversion units.

8. A solid-state imaging element comprising:
a plurality of photoelectric conversion units disposed side by side in a matrix form in a semiconductor layer; and
an on-chip lens disposed further on a light incident side than the semiconductor layer to be shared by the plurality of photoelectric conversion units, wherein
the plurality of photoelectric conversion units sharing one on-chip lens respectively receive light in five or more different wavelength regions.

9. Electronic equipment comprising:
a solid-state imaging element;
an optical system that captures incident light from a subject and forms an image on an imaging surface of the solid-state imaging element; and
a signal processing circuit that performs processing on an output signal from the solid-state imaging element, wherein
the solid-state imaging element includes:
a plurality of photoelectric conversion units disposed side by side in a matrix form in a semiconductor layer;
an on-chip lens disposed further on a light incident side than the semiconductor layer to be shared by the plurality of photoelectric conversion units;
a prism portion disposed between the on-chip lens and the plurality of photoelectric conversion units; and
a plurality of color splitters disposed between the prism portion and the plurality of photoelectric conversion units.
